(19) United States
(12) Patent Application Publication
(10) Pub. No.: US 2011/0073294 A1
(43) Pub. Date: Mar. 31, 2011

(54) SYSTEM, METHOD AND APPARATUS OF COOL TOUCH HOUSINGS

(76) Inventors: Mark MacDonald, Beaverton, OR (US); Rajiv Mongia, Fremont, CA (US)

(21) Appl. No.: 12/567,619

(22) Filed: Sep. 25, 2009

(51) Int. Cl. H05K 7/20; G06F 1/20

(52) U.S. Cl. 165/185; 165/122

(57) ABSTRACT

A system, apparatus and method for cool touch housings are described. The apparatus may include a housing arranged to at least partially enclose at least one internal component of a mobile device. A portion of the housing may include an exterior surface spreader, a thin active heat pump with a first side and a second side, wherein the first side of the thin active heat pump is thermally coupled to the exterior surface spreader, and an interior surface spreader thermally coupled to the second side of the thin active heat pump. Other embodiments are described and claimed.

### BACKGROUND

The temperature of a housing or skin of a laptop computer often increases as the computer remains in use for a period of time. The temperature of the external housing of a laptop also increases when complex or power intensive operations are performed. The computer processing unit (CPU), graphics, memory, hard drive tasks and wireless system may cause the temperature to increase. The hot temperature of the external housing, often in excess of 40° C., can make the laptop uncomfortable to place in a user's lap.

To decrease the temperature of the housing, passive insulating materials which have low thru-plane conductivity have been used. Additionally, heat spreading materials have been used with high in-plane conductivity to distribute the heat load, reducing peak temperatures. Materials used to decrease the temperature of the housing include simple plastic shells, carbon fiber, and heat pipes. However, these passive solutions are not sufficient as the housing is either too costly to effectively implement or does not dissipate the heat sufficiently causing the housing to remain too hot for comfortable use on a user's lap.

### BRIEF DESCRIPTION OF THE DRAWINGS

FIG. 1 illustrates one embodiment of a cross-sectional view of a mobile device.

FIG. 2 illustrates one embodiment of a block diagram of a section of the housing.

FIG. 3 illustrates one embodiment of a block diagram of a section of the housing.

FIG. 4 illustrates one embodiment of a logic diagram.

### DETAILED DESCRIPTION

Various embodiments may be generally directed to a system, apparatus and method for cool touch housings. In one embodiment, for example, a housing may be arranged to at least partially enclose at least one internal component of a mobile device. In one embodiment, a portion of the housing may include an exterior surface spreader, a thin active heat pump with a first side and a second side, and an interior surface spreader. The first side of the thin active heat pump may be thermally coupled to the exterior surface spreader. The interior surface spreader may be thermally coupled to the second side of the thin active heat pump. The thin active heat pump may move heat from the exterior surface spreader to the interior surface spreader. In this manner, the heat pump may be arranged to move heat from the housing to the internal components of the mobile device. Other embodiments may be described and claimed.

Various embodiments may comprise one or more elements. An element may comprise any structure arranged to perform certain operations. Each element may be implemented as hardware, software, or any combination thereof, as desired for a given set of design parameters or performance constraints. Although an embodiment may be described with a limited number of elements in a certain topology by way of example, the embodiment may include more or less elements in alternate topologies as desired for a given implementation. It is worthy to note that any reference to “one embodiment” or “an embodiment” means that a particular feature, structure, or characteristic described in connection with the embodiment is included in at least one embodiment. The appearances of the phrase “in one embodiment” in various places in the specification are not necessarily all referring to the same embodiment.

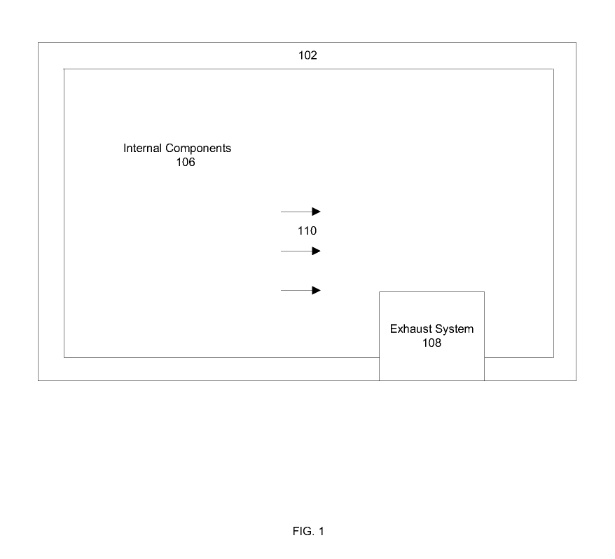

FIG. 1 is a graphical illustration of a cross-sectional view of a mobile device, in accordance with one example embodiment of the invention. As shown in FIG. 1, the mobile device may include multiple elements, such as, a housing 102, one or more internal components 106, an exhaust system 108 and/or an air flow system 110. The embodiments, however, are not limited to the elements shown in this figure.

Mobile device 100 may include a laptop, a notebook, a handheld computer, a handheld enclosure, a portable electronic device and/or a personal digital assistant. The embodiments, however, are not limited to this example.

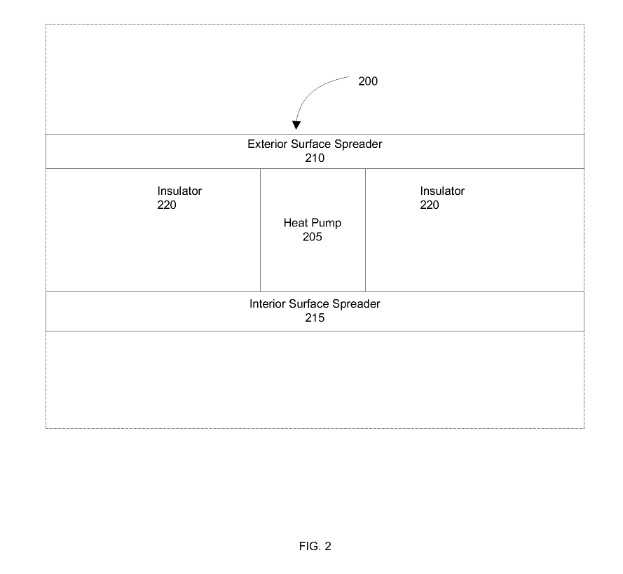

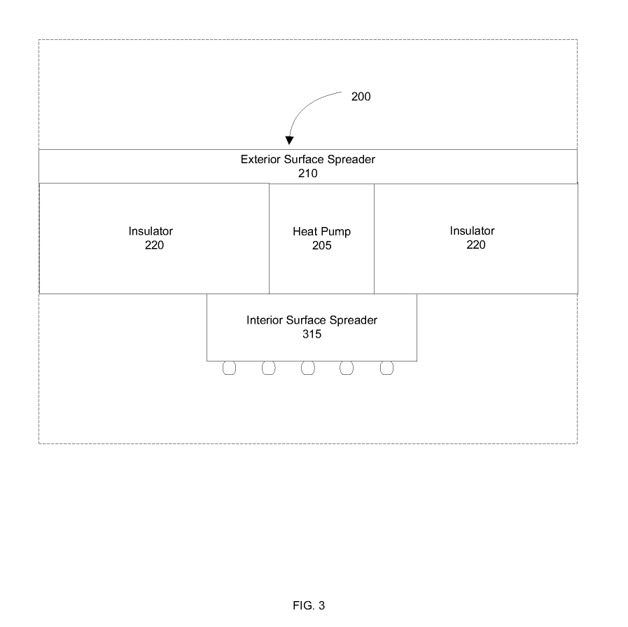

Housing 102, as described in greater detail in reference to FIGS. 2 and 3, provides a hard shell to protect the mobile device. The housing may be referred to as a skin, a chassis or a shell. In an embodiment, the housing may be used for cooling for the exterior of the mobile device 100. In one embodiment, housing 102 may be arranged to at least partially enclose at least one of the internal components 106 of a mobile device. In one embodiment, housing 102 may surround all or at least a portion of one or more internal components of a mobile device. In one embodiment, housing 102 may be in direct or indirect contact with one or more internal components 106, an exhaust system 108 and an air flow system 110.

Internal components 106 represent functional components of a mobile device 100 and may use several Watts of electricity when fully functioning. The usage of electricity by the internal components 106 may cause the mobile device 100 to generate heat and consequently increase in temperature. Internal components may include integrated circuit devices and/or a power system. The embodiments, however, are not limited to these examples. In an embodiment, the internal components may include a computer processing unit and a heatsink which needs to be cooled. The central processing unit may be placed in a location inside the mobile device 100 which allows the heat generated to be transferred out of the mobile device 100 via an exhaust system. The internal components may include a power supply, such as, but not limited to, a rechargeable battery or an outlet connection that provides electricity to the mobile device.

Exhaust system 108 may be, but is not limited to, a fan, a blower, another type of air moving device and/or a rear external exhaust device. The exhaust system 108 may be used to remove heat from the internal components of the mobile device 100. The exhaust system 108 may remove heat from the inside of the mobile device 100 to the ambient air external to the mobile device 100.

Air flow system 110 moves air within the mobile device 100. Air flow system 110 may move air toward an exhaust system 108. The airflow system may include one or more areas with a high level of airflow. The air flow may be high when it is located near an exhaust system 108. In an embodiment, the air flow system 110 may be used to move the heat out of the mobile device 100 via the exhaust system 108.

In an embodiment, the temperature of the housing 102 of the mobile device 100 may increase during use. For example, the temperate of the housing may increase from 20 to 40 degrees Celsius or more. As a result of the heat emanating from the housing, the mobile device 100 may become uncomfortable for a person to hold, interact with, or keep on their lap.

To solve these and other problems, the mobile device 100 may remove heat from the housing 102 of the mobile device 100 and transfer the heat inside the mobile device 100. For example, embedded into at least a portion of the housing 102, a heat pump may be arranged to remove heat from an exterior surface spreader and transfer the heat to an interior surface spreader. The increased heat inside the mobile device 100 may be removed using an internal air flow system 110 and an exhaust system 108. In this manner, the mobile device 100 may decrease the temperature of the housing 102. In one embodiment, the decrease in temperature may only result in a small increase of power (and/or heat). In one embodiment, the temperature of the outer surface of the housing may decrease by approximately 10-30° C. and 0.5-10 Watts may be transferred to the interior surface spreader and into the internal components and/or the air flow system of the mobile device.

In one embodiment, the electric power input to the heat pump may be 0.25-5 Watts. In one embodiment, the electric power input to the heat pump may be 1 Watt. In one embodiment, the removal of the heat from the exterior surface spreader may be 0.25-5 Watts. In one embodiment, the removal of the heat from the exterior surface spreader may be 1 Watt. In one embodiment, the interior surface spreader may absorb 0.5-10 Watts. In one embodiment, the heat absorbed by the interior surface spreader may be removed by the air flow system.

FIG. 2 illustrates one embodiment of a block diagram of a section of the housing. In an embodiment, an apparatus may be embedded into a portion of the housing 102 of a mobile device 100. As shown in FIG. 2, the apparatus 200 comprises multiple elements, such as a heat pump 205, an exterior surface spreader 210, an interior surface spreader 215 and an insulator 220. The embodiments, however, are not limited to the elements shown in this figure.

In one embodiment, apparatus 200 may comprise a heat pump 205. A heat pump 205 may comprise a solid-state active heat pump to transfer heat from one side of a device to another side against a temperature gradient. Examples of a thin active heat pump may include a thermionic device, a thermoelectric cooler, and/or a thin solid-state heat pump. The heat pump may transfer heat by consuming electrical energy. The embodiments, however, are not limited to these examples.

In one embodiment, apparatus 200 may comprise an exterior surface spreader 210 coupled to the thin active heat pump 205. Exterior surface spreader 210 may comprise an absorbing plate which may enable the entire surface of the plate to decrease in temperature. In one embodiment, an exterior surface spreader 210 may be implemented using a high thermal conductivity material. In one embodiment, an exterior surface spreader 210 may be implemented using copper, graphite, aluminum, magnesium, carbon fiber, or any other high thermal conductivity material, with or without heat pipe enhancement. The embodiments, however, are not limited to this example. In one embodiment, the exterior surface spreader may act as the outer surface of the housing and may be exposed directly to ambient air. In one embodiment, one side of the exterior surface spreader may be painted. In one embodiment, one side of the exterior surface spreader may have a plastic shell or coating. The housing comprising the eternal surface spreader may be painted or coated to look more like the rest of the external surface of the mobile device.

In one embodiment, apparatus 200 may comprise an interior surface spreader 215 coupled to the other side of the thin active heat pump 205. Interior surface spreader 215 may act as a heat exchanger. The interior surface spreader 215 may absorb a portion of the heat removed from the exterior surface spreader 210 by the thin active heat pump 205 as well as any waste heat generated by the thin active heat pump 205. In one embodiment, the electric power input to the thin active heat pump may be 0.25-5 Watts. In one embodiment, the electric power input to the thin active heat pump may be 1 Watt. In one embodiment, the removal of the heat from the exterior surface spreader may be 0.25-5 Watts. In one embodiment, the removal of the heat from the exterior surface spreader may be 1 Watt. In one embodiment, the interior surface spreader may absorb 0.5-10 Watts. In one embodiment, the heat absorbed by the interior surface spreader may be removed by the air flow system.

In one embodiment, the interior surface spreader 215 may be an absorbing plate which acts as a heat exchanger. In one embodiment, an interior surface spreader 215 may be implemented using a high thermal conductivity material. In one embodiment, an interior surface spreader 215 may be implemented using copper, graphite and/or aluminum. The embodiments, however, are not limited to this example.

In one embodiment, as depicted in FIG. 2, the interior surface spreader 215 may be an absorbing plate. In an embodiment, the interior surface spreader 215 may be an absorbing plate with a thin width. In one embodiment, the surface area of the interior surface spreader may be equal to the surface area of the exterior surface spreader. In one embodiment, the surface area of the interior surface spreader may be larger than the surface area of the exterior surface spreader. In one embodiment, the surface area of the interior surface spreader may be smaller than the surface area of the exterior surface spreader. In one embodiment, the thickness of the interior surface spreader may be equal to the thickness of the exterior surface spreader. In one embodiment, the thickness of the interior surface spreader may be larger than the thickness of the exterior surface spreader. In one embodiment, the thickness of the interior surface spreader may be smaller than the thickness of the exterior surface spreader.

In one embodiment, the interior surface spreader may be a rectangular or square box-shaped piece with a plurality of small protrusions on one side. FIG. 3 illustrates one embodiment of a block diagram of a section of the housing with the interior surface spreader comprising a rectangular box-shaped piece with a plurality of small protrusions. In one embodiment, the size of the box-shaped piece and the number of protrusions may vary based on the location of the apparatus, the surface area and/or the amount of air flow received.

In one embodiment, the bottom side of the rectangular box-shape, the side opposite the protrusions, may be coupled to the thin active heat pump 205. In one embodiment, the small protrusions may absorb the transferred heat. The interior surface spreader 315 may be in a location that allows the protrusions to be exposed to the air flow system. For example, the apparatus may be embedded inside housing that is placed above at least one internal component which is positioned in a high air flow area of the air flow system.

In one embodiment, the configuration of the rectangular box-shape with protrusions may be chosen for the interior surface spreader 215 because the shape of the rectangular box-shape with protrusions may allow a lower operating temperature for the interior surface spreader, allowing less heat to be lost through the insulator 220 to the exterior surface spreader 210. In one embodiment, the box with protrusions may have a smaller surface area. In one embodiment, a thin absorbing plate may be chosen as interior surface spreader 215 because it may result in a thinner thickness of the housing.

In one embodiment, apparatus 200 may comprise an insulator 220 located between the exterior surface spreader 210 and the interior surface spreader 215. In one embodiment, the insulator may be on both sides of the thin active heat pump 205. For example, the thin active heat pump 205 may be located in the center of the interior surface spreader and the exterior surface spreader, with the insulator on both sides. In one embodiment, the thin active heat pump 205 may be located anywhere from the center of the interior and/or exterior surface spreaders to the periphery of the interior and/or exterior surface spreaders with the insulator on one or both sides of the thin active heat pump 205.

The insulator 220 may provide resistance to decrease the amount of heat leaving the hot interior surface spreader 215. In one embodiment, the insulator 220 may allow some heat to pass from the interior surface spreader 215 to the exterior surface spreader 210. In one embodiment, the thin active heat pump 205 may remove at least as much heat from the exterior surface spreader 210 as the insulator 220 allows to enter the exterior surface spreader 210. In one embodiment, an insulator 220 may be implemented using Styrofoam, fiberglass and/or an air gap. The embodiments, however, are not limited to this example.

In general operation, apparatus 200 may remove heat from the exterior surface spreader 210 and transfer the heat, plus any waste heat generated by the thin active heat pump 205, to the interior surface spreader 215. The insulator 220 may decrease the transfer of the heat from the interior surface spreader 215 back to the exterior surface spreader 210. In one embodiment, the thin active heat pump 205 removes at least as much heat from the exterior surface spreader 210 as the insulator 220 allows to enter the exterior surface spreader 210 from the interior surface spreader 215. In one embodiment, the heat may be simultaneously removed from the interior surface spreader by the airflow and the exhaust systems.

In one embodiment, apparatus 200 creates a very high thermal resistance between the high temperature internal components 106 and the exterior surface spreader 210. In an embodiment, the resistance between the internal components 106 and the exterior surface spreader 210 may be infinite, and may act as a perfect insulator. In one embodiment, there may be an infinite or very high thermal resistance when the exterior surface spreader is approximately the same temperature as the ambient air external to the mobile device. There may be no net heat flow out of the exterior surface spreader 210 into the ambient air. In one embodiment, the apparatus 200 may create a temperature on the exterior surface spreader 210 that is below the ambient temperature and the thermal resistance between the high temperature internal components 106 and the exterior surface spreader 210 may be negative as the heat may be pumped from the cool ambient temperature into the hot internal components. In one embodiment, there may be a negative thermal resistance when the exterior surface spreader 210 has a temperature lower than the ambient temperature external to the mobile device. Heat may flow from the ambient air into the exterior surface spreader 210.

In one embodiment, the removal of the heat from the exterior surface spreader 210 may result in the housing temperature decreasing approximately 10-30° C. In one embodiment, the removal of the heat from the exterior surface spreader 210 may result in the housing temperature decreasing approximately 20° C. The embodiments, however, are not limited to this example.

In an embodiment, the decrease in temperature may result in a small increase in heat which may be created by energy consumed by the thin active heat pump. In one embodiment, the decrease of heat by 10-30° C. from the exterior surface spreader 210 may result in the transfer of 0.5-10 Watts to the interior surface spreader.

In one embodiment, the removal or decrease of heat from the exterior surface spreader 210 may consume approximately 1 Watt of power. In one embodiment, the removal or decrease of heat from the exterior surface spreader 210 may consume less than approximately 1 Watt of power. The embodiments, however, are not limited to this example.

Operations for the above embodiments may be further described with reference to the following figures and accompanying examples. Some of the figures may include a logic flow. Although such figures presented herein may include a particular logic flow, it can be appreciated that the logic flow merely provides an example of how the general functionality as described herein can be implemented. Further, the given logic flow does not necessarily have to be executed in the order presented unless otherwise indicated. In addition, the given logic flow may be implemented by a hardware element, a software element executed by a processor, or any combination thereof. The embodiments are not limited in this context.

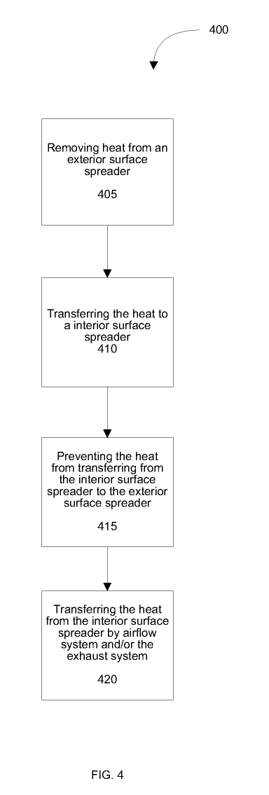

FIG. 4 illustrates one embodiment of a logic flow. FIG. 4 illustrates a logic flow 400. Logic flow 400 may be representative of the operations executed by one or more embodiments described herein. As shown in logic flow 400, at least a portion of the heat may be removed 405 from an exterior surface spreader. In one embodiment, heat from an exterior surface spreader may be removed, via a thin active heat pump embedded in a portion of a housing of a mobile device, to decrease the temperature of the housing. In an embodiment, heat from an exterior surface spreader may be removed 405 to decrease a temperature of the housing. In one embodiment, the exterior surface spreader may be embedded within a part of the housing which may be in contact with ambient temperature. In one embodiment, the exterior surface spreader may the exterior portion of the housing which may be in contact with ambient temperature.

In one embodiment, the heat may be transferred to 410 to an interior surface spreader. The interior surface spreader may be embedded within a portion of the housing and may be in direct or indirect contact with one or more internal components of the mobile device. In one embodiment, the heat may be transferred to 410 via the thin active heat pump. In one embodiment, the heat may be released to an interior surface spreader which may increase the temperature inside the mobile device.

In an embodiment, the interior surface spreader may by located by at least one of the internal components and the air flow system. In one embodiment, heat may be transferred 420 from the interior surface spreader by airflow system. In one embodiment, the heat may be transferred 420 from the interior surface spreader via the airflow system to the exhaust system. In one embodiment, heat may be transferred from the interior surface spreader via the air flow system. In one embodiment, the heat may be transferred 420 from the interior surface spreader by the exhaust system.

In one embodiment, the heat transferred to the interior surface spreader may tend to leak back toward the exterior surface spreader. In one embodiment, the heat from the interior surface spreader may be prevented 415 from transferring to the exterior surface spreader.

In one embodiment, the thin active heat pump embedded in the housing may create an extremely high thermal resistance for the housing. In one embodiment, an infinite resistance may be retained between the exterior surface spreader and the interior surface spreader. In one embodiment, a negative resistance may be maintained between the exterior surface spreader and the interior surface spreader. In one embodiment, the apparatus may act as an active thermal insulator.

In an embodiment, a low amount of energy and/or heat may be consumed during the use of the thin active heat pump. In one embodiment, the electric power input to the heat pump may be 0.25-5 Watts. In one embodiment, the electric power input to the heat pump may be 1 Watt. In one embodiment, the removal of the heat from the exterior surface spreader may be 0.25-5 Watts. In one embodiment, the removal of the heat from the exterior surface spreader may be 1 Watt. In one embodiment, the interior surface spreader may absorb 0.5-10 Watts. In one embodiment, the heat absorbed by the interior surface spreader may be removed by the air flow system.

In an embodiment, the thin active heat pump may be activated by an on-demand mode. In one embodiment, the on-demand mode may be part of a thermal management system. The on-demand mode may reduce the power consumption of the thin active heat pump. In one embodiment, the thin active heat pump may be activated when the mobile device is in a high performance mode, when the thin active heat pump is plugged in to an electric outlet, or when the housing reaches a threshold temperature. For example, the mobile device may include a sensor which determines the external temperature of the housing. If the external temperature of the housing is greater than a threshold temperature, the mobile device may activate the thin active heat pump. In one embodiment, the threshold temperature may be between 20-40° C. In one embodiment, the threshold temperature may be 25° C. The embodiments, however, are not limited to this example.

Numerous specific details have been set forth herein to provide a thorough understanding of the embodiments. It will be understood by those skilled in the art, however, that the embodiments may be practiced without these specific details. In other instances, well-known operations, components and circuits have not been described in detail so as not to obscure the embodiments. It can be appreciated that the specific structural and functional details disclosed herein may be representative and do not necessarily limit the scope of the embodiments.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

It should be noted that the methods described herein do not have to be executed in the order described, or in any particular order. Moreover, various activities described with respect to the methods identified herein can be executed in serial or parallel fashion.

Although specific embodiments have been illustrated and described herein, it should be appreciated that any arrangement calculated to achieve the same purpose may be substituted for the specific embodiments shown. This disclosure is intended to cover any and all adaptations or variations of various embodiments. It is to be understood that the above description has been made in an illustrative fashion, and not a restrictive one. Combinations of the above embodiments, and other embodiments not specifically described herein will be apparent to those of skill in the art upon reviewing the above description. Thus, the scope of various embodiments includes any other applications in which the above compositions, structures, and methods are used.

It is emphasized that the Abstract of the Disclosure is provided to comply with 37 C.F.R. .sctn. 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment. In the appended claims, the terms “including” and “in which” are used as the plain-English equivalents of the respective terms “comprising” and “wherein,” respectively. Moreover, the terms “first,” “second,” and “third,” etc. are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An apparatus comprising:
a housing arranged to at least partially enclose at least one internal component of a mobile device;
a portion of the housing comprising:
an exterior surface spreader;
a thin active heat pump with a first side and a second side, wherein the first side of the thin active heat pump is thermally coupled to the exterior surface spreader; and
an interior surface spreader thermally coupled to the second side of the thin active heat pump.

2. The apparatus of claim 1 wherein the thin active heat pump is arranged to move heat from the exterior surface spreader to toward an airflow area in the mobile device.

3. The apparatus of claim 1 wherein the housing further comprises:
a plastic shell surrounding a portion of the exterior surface spreader.

4. The apparatus of claim 1 wherein the housing further comprises:
an insulator between the interior surface spreader and the exterior surface spreader to prevent heat from leaving the interior surface spreader and entering the exterior surface spreader.

5. The apparatus of claim 1 wherein the interior surface spreader comprises a heat exchanger.

6. The apparatus of claim 1 wherein the thin active heat pump to remove at least as much heat from the exterior surface spreader as the insulator would allow to enter the exterior surface spreader from the interior surface spreader.

7. The apparatus of claim 1 wherein the exterior surface spreader comprises one or more of a copper, graphite and aluminum plate.

8. The apparatus of claim 1 wherein the interior surface spreader comprises one or more of a copper, graphite and aluminum plate.

9. The apparatus of claim 1 wherein the interior surface spreader comprises a rectangular box with protrusions.

10. A system, comprising:
at least one internal component; and
a portion of a housing arranged to at least partially enclose the at least one internal component, the housing comprising:
an exterior surface spreader,
a thin active heat pump with a first side and a second side, wherein the first side of the thin active heat pump is thermally coupled to the exterior surface spreader, and
an interior surface spreader thermally coupled to the second side of the thin active heat pump, and an exhaust system to remove heat from the interior surface spreader.

11. The system of claim 10, wherein the thin active heat pump is arranged to move heat from the exterior surface spreader to the interior surface spreader.

12. The system of claim 10 wherein the interior surface spreader is located in an air flow system.

13. A method, comprising:
removing, via a thin active heat pump embedded in a portion of a housing of a mobile device, heat from an exterior surface spreader to decrease a temperature of the housing; and
transferring the heat to an interior surface spreader.

14. The method of claim 13 wherein transferring the heat to an interior surface spreader comprises increasing a temperature inside the mobile device.

15. The method of claim 13, further comprising:
transferring heat from the interior surface spreader via an air flow system.

16. The method of claim 13, further comprising:
preventing a portion of the heat from transferring from the interior surface spreader to the exterior surface spreader.

17. The method of claim 13, further comprising:
maintaining a very high resistance between the exterior surface spreader and the interior surface spreader.

18. The method of claim 13, further comprising:
maintaining a negative resistance between the exterior surface spreader and the interior surface spreader.

19. The method of claim 13, further comprising:
activating the thin active heat pump by an on-demand mode.

20. The method of claim 13, wherein transferring the heat to an interior surface spreader requires approximately 1 Watt of power.
